(19) United States
(12) Patent Application Publication
(10) Pub. No.: US 2025/0048730 A1
(43) Pub. Date: Feb. 6, 2025

(54) RELEASE LAYER CONTAINING SEMICONDUCTOR-ON-INSULATOR SUBSTRATES

(71) Applicant: International Business Machines Corporation, Armonk, NY (US)

(72) Inventors: John Knickerbocker, Monroe, NY (US); Qianwen Chen, Chappaqua, NY (US); Akihiro Horibe, Yokohama (JP); Michael P. Belyansky, Halfmoon, NY (US); Spyridon Skordas, Troy, NY (US)

(21) Appl. No.: 18/228,946

(22) Filed: Aug. 1, 2023

(51) Int. Cl. H01L 27/12

(52) U.S. Cl. CPC H01L 27/1203

(57) ABSTRACT

SOI substrates containing an embedded release layer that is composed of a transition metal-containing material that has high temperature stability, is infrared energy absorbing, and is compatible with complementary metal oxide semiconductor (CMOS), front-end-of-the-line (FEOL) and back-end-of-the-line (BEOL) processes are provided. The presence of the embedded release layer in the SOI substrates allows for rapid substrate thinning/removal by infrared ablation without the need of using grinding, polishing and etching methods.

### BACKGROUND

The present application relates to semiconductor technology, and more particularly to semiconductor-on-insulator (SOI) substrates that include an embedded release layer.

SOI technology is one of several manufacturing strategies to allow the continued miniaturization of microelectronic devices. Reported benefits of SOI relative to conventional bulk (i.e., Si) processing include (i) lower parasitic capacitance due to isolation from the bulk silicon, which improves power consumption at matched performance, (ii) resistance to latch-up due to complete isolation of the n- and p-well structures, (iii) higher performance at equivalent VDD, (iv) reduced temperature dependency due to no doping, (v) better yield due to high density, better wafer utilization, (vi) reduced antenna issues, (vii) no body or well taps are needed, (viii) lower leakage currents due to isolation thus higher power efficiency, (ix) inherently radiation hardened (resistant to soft errors), reducing the need for redundancy and/or any combination thereof.

In current practice, one of the semiconductor layers of the SOI substrate includes one or more semiconductor device located thereon, and the other semiconductor layer serves as a base substrate which together with the insulator layer can be removed to allow backside processing of the semiconductor layer that includes the one or more semiconductor devices. The removal of the base substrate and the insulator layer from the SOI substrate typically includes grinding, polishing and etching methods.

### SUMMARY

SOI substrates containing an embedded release layer are provided. The release layer can be a permanent layer within the SOI substrates, or it can be a temporary layer within the SOI substrates. The release layer of the present application is composed of a transition metal-containing material that has high temperature stability, is infrared energy absorbing, and is compatible with complementary metal oxide semiconductor (CMOS), front-end-of-the-line (FEOL) and back-end-of-the-line (BEOL) processes. The presence of the embedded release layer in the SOI substrates allows for rapid substrate thinning/removal by infrared ablation without the need of using grinding, polishing and etching methods. Grinding/polishing/etching methods have low throughput and can cause high stress and damage to an SOI substrate that does not contain the embedded release layer.

In one embodiment, the SOI substrate includes a first semiconductor layer, a release layer located on a first surface of the first semiconductor layer, a first dielectric layer located on the release layer, and a second semiconductor layer located on the first dielectric layer. Throughout the present application, the term “first dielectric layer” denotes a single dielectric layer or a multilayered stack of dielectric layers. In accordance with the present application, the release layer is an infrared energy absorbing transition metal-containing material having a melting temperature that is greater than 1000° C.

In some embodiments, the SOI substrate can further include an antireflection layer positioned on a second surface of the first semiconductor layer, wherein the second surface is opposite the first surface.

In some embodiments, the SOI substrate can further include a first antireflection layer positioned between the first semiconductor layer and the release layer, wherein the first antireflection layer contacts the first surface of the first semiconductor layer. In such embodiments, a second antireflection layer can be present that contacts a second surface of the first semiconductor layer, wherein the second surface of the first semiconductor layer is opposite the first surface of the first semiconductor layer.

In some embodiments, the SOI substrate can further include an infrared barrier layer located on the first dielectric layer, and a second dielectric layer located on the infrared barrier layer, wherein the infrared barrier layer and the second dielectric layer are sandwiched between the first dielectric layer and the second semiconductor layer. Throughout the present application, the term “second dielectric layer” denotes a single dielectric layer or a multilayered stack of dielectric layers.

### BRIEF DESCRIPTION OF THE DRAWINGS

FIG. 1A is a cross-sectional view of an exemplary SOI substrate in accordance with a first embodiment of the present application.

FIG. 1B is a cross-sectional view of exemplary SOI substrate in accordance with a second embodiment of the present application.

FIG. 2A is a first variation of the exemplary SOI substrate of FIG. 1A.

FIG. 2B is a first variation of the exemplary SOI substrate of FIG. 1B.

FIG. 3A is a second variation of the exemplary SOI substrate of FIG. 1A.

FIG. 3B is a second variation of the exemplary SOI substrate of FIG. 1B.

FIG. 4A is a third variation of the exemplary SOI substrate of FIG. 1A.

FIG. 4B is a third variation of the exemplary SOI substrate of FIG. 1B.

FIG. 5 a cross-sectional view of exemplary SOI substrate shown in FIG. 1B and during an initial step of infrared exposure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The present application provides SOI substrates that include an embedded release layer. The embedded release layer is composed of a transition metal-containing material that has high temperature stability, is infrared energy absorbing, and is compatible with CMOS, FEOL and BEOL processes. The presence of the embedded release layer in the SOI substrates allows for rapid substrate thinning/removal by infrared ablation without the need of using grinding, polishing and etching methods. The SOI substrates of the present application can be used for three dimensional (3D) semiconductor applications, and for high integration (HI) density applications. These and other aspects of the present application will now be described in greater detail.

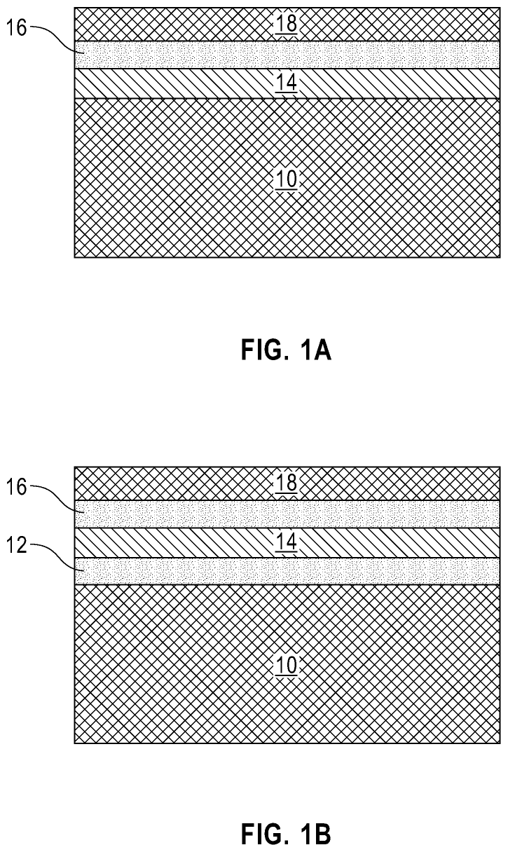

Referring first to FIG. 1A, there is illustrated an exemplary SOI substrate in accordance with a first embodiment of the present application. The exemplary SOI substrate of this first embodiment illustrated in FIG. 1 includes a first semiconductor layer 10, a release layer 14 located directly on a first surface of the first semiconductor layer 10, a first dielectric layer 16 (single or multilayered) located directly on the release layer 14, and a second semiconductor layer 18 located directly on the first dielectric layer 16. In this first embodiment, the release layer 14 forms a material interface with the first surface of the first semiconductor layer 10, the first dielectric layer 16 forms a material interface with the release layer 14, and the second semiconductor layer 18 forms a material interface with the first dielectric layer 16.

The first semiconductor layer 10 is composed of a first semiconductor material, while the second semiconductor layer 18 is composed of a second semiconductor material. In the present application, the first semiconductor layer 10 serves as a base (handle) substrate, while the second semiconductor layer 18 serves as a device layer in which one or more semiconductor devices (e.g., transistors, diodes and/capacitors) can be formed. Throughout the present application, the term “semiconductor material” denotes a material that has semiconducting properties. Examples of semiconductor materials that can be used in the present application in providing the first semiconductor layer 10 and the second semiconductor layer 18 include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments of the present application, the first semiconductor material that provides the first semiconductor layer 10 is compositionally the same as the second semiconductor material that provides the second semiconductor layer 18. In one example, both the first semiconductor layer 10 and the second semiconductor layer 18 are composed of Si. In other embodiments, the first semiconductor material that provides the first semiconductor layer 10 is compositionally different from the second semiconductor material that provides the second semiconductor layer 18. In one example, the first semiconductor layer 10 is composed of Si and the second semiconductor layer 18 is composed of a SiGe alloy.

In the present application, the first semiconductor layer 10 has a first thickness, while the second semiconductor layer 18 has a second thickness, wherein the second thickness is less than the first thickness. In one example, the first thickness is 50 μm to 1000 μm, and the second thickness is from 1 nm to 100 μm (e.g., 100,000 nm).

The release layer 14 is an infrared energy absorbing transition metal-containing material having a melting temperature that is greater than 1000° C. In some embodiments, the melting point of the infrared energy absorbing transition metal-containing material that provides the release layer 14 is from 1450° C. to 3200° C. The transition metal-containing material includes at least one chemical element in the d-block of the Periodic Table of Elements (i.e., transition metals from Groups 3 to 12 of the Periodic Table of Elements) or as least one chemical element from the f-block (i.e., inner transition metals or the lanthanide and actinide elements).

In some embodiments, the infrared energy absorbing transition metal-containing material that provides the release layer 14 is a transition metal, a transition metal alloy, or a transition metal composite including for example, a transition metal nitride. Illustrative examples of transition metals that can be used as the infrared energy absorbing transition metal-containing material that provides the release layer 14 include, but are not limited to, titanium, tantalum, tungsten, cobalt, chromium, ruthenium, platinum, or palladium. Transition metal alloys include at least two transition metals such as, for example, a cobalt-tungsten alloy. Illustrative examples of transition metal nitrides that can be used as the infrared energy absorbing transition metal-containing material that provides the release layer 14 include, but are not limited to, titanium nitride, tantalum nitride, or tungsten nitride.

The thickness of the release layer 14 can vary so long as the thickness does not adversely affect the stability and infrared energy absorbing capability of the release layer 14. The release layer 14 typically has a thickness from 1 nm to 200 nm.

The first dielectric layer 16 (single or multilayered) is composed of at least one dielectric material such as, for example, silicon dioxide, silicon nitride, silicon oxynitride, boron nitride, aluminum nitride, beryllium dioxide, a diamond film (such as, for example, diamond-like carbon) or any combination thereof. For example, the first dielectric layer 16 is multilayered containing a layer of silicon dioxide and a layer of boron nitride, or a layer of silicon dioxide and a layer of silicon nitride. The thickness of the first dielectric layer 16 can vary. Typically, the first dielectric layer 16 has a thickness from 10 nm to 10 μm (e.g., 10000 nm); although other thicknesses are contemplated and can be used as the thickness of the first dielectric layer 16.

The first dielectric layer 16 (single layered or multilayered) can provide electrical insulation and optionally can provide enhanced thermal heat transport and/or heat spreading.

Referring now to FIG. 1B, there is illustrated exemplary SOI substrate in accordance with a second embodiment of the present application. The exemplary SOI substrate of the second embodiment that is illustrated in FIG. 1B includes first semiconductor layer 10, as defined above, a first antireflection layer 12, release layer 14, as defined above, first dielectric layer 16, as defined above, and second semiconductor layer 18, as defined above. In this second embodiment, the first antireflection layer 12 is located directly on, and thus forms a material interface with, the first surface of the first semiconductor layer 10, the release layer 14 is located directly on, and thus forms a material interface with, the first antireflection layer 12, the first dielectric layer 16 is located on, and thus forms a material interface with, the release layer 14, and the second semiconductor layer 18 is located directly on, and thus forms a material interface with the first dielectric layer 16. The second embodiment illustrated in FIG. 1B is similar to the first embodiment illustrated in FIG. 1A, except for the first antireflection layer 12 which is sandwiched between the release layer 14 and the first semiconductor layer 10.

The first antireflection layer 12 (which can be single layered or multilayered) is composed of any antireflective material that is CMOS/FEOL/BEOL compatible. Illustrative examples of antireflective materials that can be used as the first antireflection layer 12 include, but are not limited to, silicon dioxide, silicon nitride, silicon carbon nitride, tetraethyl-orthosilicate (TEOS) and multilayered stacks thereof. The presence of the first antireflection layer 12 can enhance the infrared absorption rate of the release layer 14. The thickness of the first antireflection layer 12 can vary. Typically, the first antireflection layer 12 has a thickness from 10 nm to 5 μm (e.g., 5000 nm); although other thicknesses are contemplated and can be used as the thickness of the first antireflection layer 12.

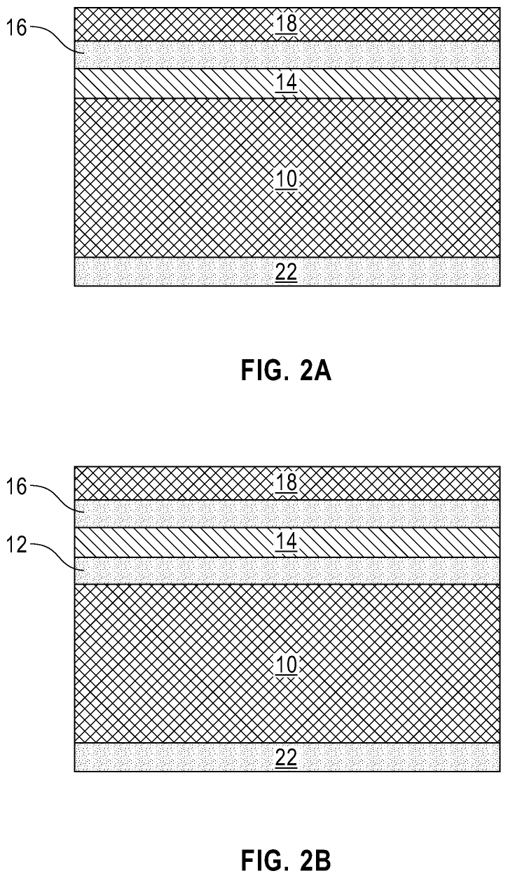

Reference is now made to FIG. 2A which is a first variation of the exemplary SOI substrate of FIG. 1A, and FIG. 2B which is a first variation of the exemplary SOI substrate of FIG. 1B. Each of the illustrated first variations includes an antireflection layer 22 (which can be single layered or multilayered) located directly on a second surface of the first semiconductor layer 10. In the present application, the second surface of the first semiconductor layer 10 is opposite from the first surface of the first semiconductor layer 10; and the second surface of the first semiconductor layer 10 is further from the second semiconductor layer 18 than the second surface of the first semiconductor layer 10. In the embodiments, in which the first antireflection layer 12 is present, antireflection layer 22 represents a second antireflection layer present in the SOI substrate.

The antireflection layer 22 is composed of any antireflective material that is CMOS/FEOL/BEOL compatible. Illustrative examples of antireflective materials that can be used as the antireflection layer 22 include, but are not limited to, silicon dioxide, silicon nitride, silicon carbon nitride, tetraethyl-orthosilicate (TEOS) and multilayered stacks thereof. In embodiments in which the first antireflection layer 12 is also present, antireflection layer 22 can be composed of an antireflective material that is compositionally the same as, or compositionally different from, the antireflective material that provides the first antireflective layer 12. The presence of the antireflection layer 22 can enhance the infrared absorption rate of the release layer 14. The thickness of the antireflection layer 22 can vary. Typically, the first antireflection layer 12 has a thickness from 10 nm to 5 μm (e.g., 5000 nm); although other thicknesses are contemplated and can be used as the thickness of the antireflection layer 22.

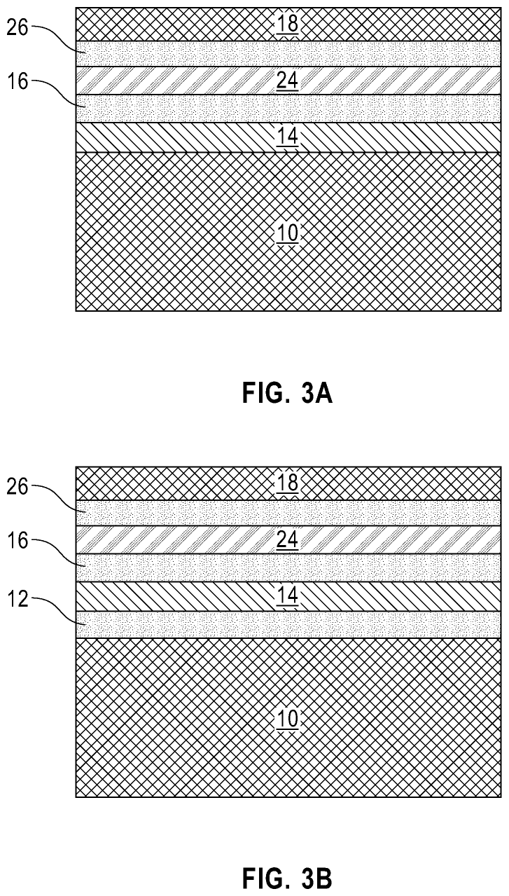

Reference is now made to FIG. 3A which is a second variation of the exemplary SOI substrate of FIG. 1A, and FIG. 3B which is a second variation of the exemplary SOI substrate of FIG. 1B. Each of the illustrated second variations includes an infrared barrier layer 24 (which can be single layered or multilayered) located on the first dielectric layer 16, and a second dielectric layer 26 (which can be single layered or multilayered) located on the infrared barrier layer 24. In the second variations, the infrared barrier layer 24 and the second dielectric layer 26 are sandwiched between the first dielectric layer 16 and the second semiconductor layer 18.

The infrared barrier layer 24 protects the one or more semiconductor devices that are subsequently formed on the second semiconductor layer 18 from being damaged during the removal of at least the first semiconductor layer 10 by laser ablating the release layer 14. The infrared barrier layer 24 can be a temporary layer that is subsequently removed after laser ablation of the release layer 14, or it can be a permanent layer that remains after laser ablation. The infrared barrier layer 24 is infrared reflective and has substantially zero infrared transmittance. By “substantially zero infrared transmittance” it is meant that the infrared barrier layer 24 has zero infrared transmittance or an infrared transmittance that is at least 10% from zero infrared transmittance. The infrared barrier layer 24 is composed of a metal-containing material such as, for example, titanium, titanium nitride, copper, tantalum, tantalum nitride, chromium, ruthenium, cobalt, tungsten, platinum and/or palladium. Note that the metal-containing material that provides the infrared barrier layer 24 is thick so that laser ablation does not occur in that region of the SOI substrate. Notably, the infrared barrier layer 24 has a thickness from 20 nm to 5 μm (e.g., 5000 nm).

The second dielectric layer 26 (single layered or multilayered) is composed of at least one dielectric material such as, for example, silicon dioxide, silicon nitride, silicon oxynitride, boron nitride, aluminum nitride, beryllium dioxide, a diamond film (such as, for example, diamond-like carbon) or any combination thereof. The dielectric material that provides the second dielectric layer 26 can be compositionally the same as, or compositionally different from, the dielectric material that provides the first dielectric layer 16. The thickness of the second dielectric layer 26 can vary. Typically, the second dielectric layer 26 has a thickness from 1 nm to 5 μm (e.g., 5000 nm); although other thicknesses are contemplated and can be used as the thickness of the second dielectric layer 26.

The second dielectric layer 26 (single layered or multilayered) can provide electrical insulation and optionally can provide enhanced thermal heat transport and/or heat spreading.

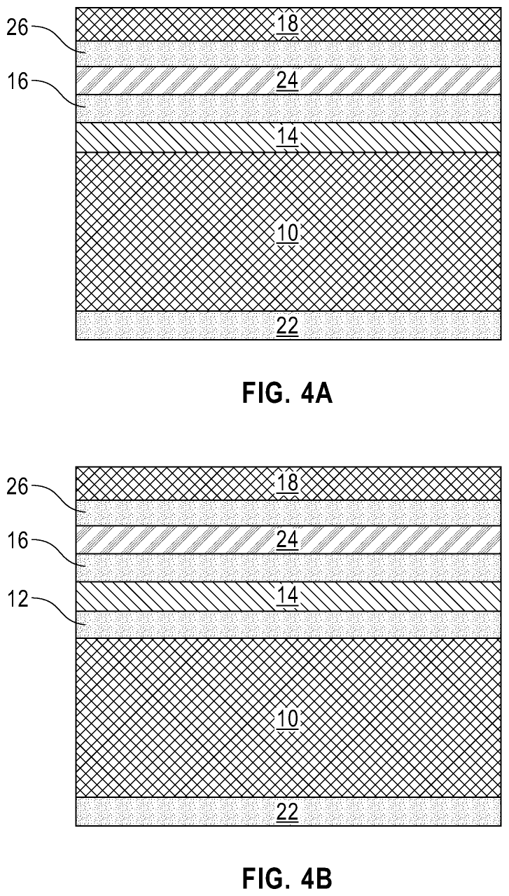

Reference is now made to FIG. 4A which is a third variation of the exemplary SOI substrate of FIG. 1A, and FIG. 4B which is a third variation of the exemplary SOI substrate of FIG. 1B. Each of the illustrated third variations includes antireflection layer 22, as defined above, as well infrared barrier layer 24, as defined above, located on the first dielectric layer 16, and second dielectric layer 26, as defined above, located on the infrared barrier layer 24. In the third variations, the antireflection layer 22 is located on a second surface of the first semiconductor layer 10, and the infrared barrier layer 24 and the second dielectric layer 26 are sandwiched between the first dielectric layer 16 and the second semiconductor layer 18.

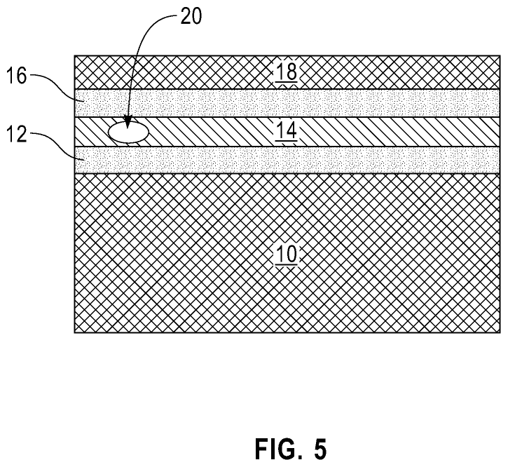

Referring now to FIG. 5, there is illustrated the exemplary SOI substrate shown in FIG. 1B and during an initial step of infrared exposure 20. The infrared exposure can be conducted at a wavelength that facilitates the ablation of the release layer 14. In some embodiments, the infrared exposure is performed at a wavelength from 1 μm to 10 μm. In some embodiments, the infrared exposure is performed utilizing a laser.

Upon completion of the infrared exposure, the entire release layer 14 is ablated releasing at least the first semiconductor layer 10 from the remaining portions of the SOI substrate shown in FIG. 5. When present, reflection layer 22 and the first antireflection layer 12 can also be removed after completion of the infrared exposure. In the illustrated embodiment of FIG. 5, the first dielectric layer 16 and the second semiconductor layer 18 remain together after completion of the infrared exposure. In embodiments in which the infrared barrier layer 24 and the second dielectric layer 26 are present, those layers remain with the first dielectric layer 16 and the second semiconductor layer 18 after the laser ablation process. Any one of, or any combination of, or all of, the first dielectric layer 16, the infrared barrier layer 24 and the second dielectric layer 26 can be permanent layers. Alternatively, any one of, or any combination of, or all of, or the first dielectric layer 16, the infrared barrier layer 24 and the second dielectric layer 26 can be removed (by etching) to allow backside processes of the second semiconductor layer 18.

The SOI substrates of the present application (including those illustrated in FIGS. 1A-4B) can be formed utilizing techniques well known to those skilled in the art. In one embodiment, the SOI substrates can be formed by successively depositing each layer (i.e., optional first antireflection layer 12, release layer 14, first dielectric layer 16, optional barrier layer 24, optional second dielectric layer 26, and second semiconductor layer 18) on top of the first surface of the first semiconductor layer 10; when the antireflection coating layer 22 is present, the antireflection coating layer 22 is typically formed on the second surface of the first semiconductor layer 10 after depositing the second semiconductor layer 18. The deposition can include, but is not limited to, chemical vapor deposition (CVD), plasma enhanced vapor deposition (PECVD), physical vapor deposition (PVD) or epitaxial growth (typically used in forming the second semiconductor layer 18) and/or a thermal anneal process.

In another embodiment, the SOI substrates can be formed utilizing a wafer bonding process. In one example, the wafer bonding process can include first selecting top blanket semiconductor wafers. On one of the wafers (hereinafter a first wafer), a portion of the first dielectric layer 16 is formed by deposition or a thermal growth process (e.g., thermal oxidation). On the other wafer (hereinafter a second wafer), the optional first antireflection layer 12, the release layer 14, and another portion of the first dielectric layer 16 are formed. Wafer bonding is then performed by bringing the two portions of the first dielectric layer 16 into intimate contact with each other, and then heating the contacted structures at a temperature that facilitates wafer-to-wafer bonding, fusion bonding, or any alternative bonding process(es). The second wafer can then be thinned utilizing thinning techniques that are well known to those skilled in the art. The wafer bonding process can be modified to include the optional infrared barrier layer 24 and optional the second dielectric layer 26. The optional antireflection layer 22 can be formed on the first wafer any time during the bonding process.

In embodiments of the present application, the first semiconductor layer 10 can be a permanent layer or a temporary layer which is removed from other layers of the SOI substrate after laser ablation. In embodiments of the present application, the optional first antireflection layer 12 and/or the second antireflection layer 22 can be a permanent layer or a temporary layer which together with the first semiconductor layer 10 are removed from other layers of the SOI substrate after laser ablation. In embodiments of the present application, the release layer 14 can be a permanent layer (when no laser ablation is employed) or a temporary layer (when laser ablation is employed). In any or the embodiments of the present application, the first dielectric layer 16 and the second semiconductor layer 18 can remain attached (before and after laser ablation) and are permanent layers. In embodiments of the present application, the optional infrared barrier layer 24 and the optional second dielectric layer 26 remain attached to the second semiconductor layer (before and after laser ablation) and thus both are permanent layers. In embodiments in which a second dielectric layer 26 is employed it is possible to remove the first dielectric layer 16 and the infrared barrier layer 24 after laser ablation leaving the second dielectric layer 26 attached to the second semiconductor layer 18.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor-on-insulator (SOI) substrate comprising:
a first semiconductor layer;
a release layer located on a first surface of the first semiconductor layer and comprising an infrared energy absorbing transition metal-containing material having a melting temperature that is greater than 1000° C.;
a first dielectric layer located on the release layer; and
a second semiconductor layer located on the first dielectric layer.

2. The SOI substrate of claim 1, wherein the infrared energy absorbing transition metal-containing material comprises a transition metal, a transition metal alloy, or a transition metal composite

3. The SOI substrate of claim 2, wherein the transition metal comprises titanium, tantalum, tungsten, cobalt, chromium, ruthenium, platinum, or palladium.

4. The SOI substrate of claim 2, wherein the transition metal composite is a transition metal nitride.

5. The SOI substrate of claim 1, wherein the release layer has a thickness from 1 nm to 200 nm.

6. The SOI substrate of claim 1, further comprising an antireflection layer positioned on a second surface of the first semiconductor layer, wherein the second surface is opposite the first surface.

7. The SOI substrate of claim 1, further comprising an infrared barrier layer located on the first dielectric layer, and a second dielectric layer located on the infrared barrier layer, wherein the infrared barrier layer and the second dielectric layer are sandwiched between the first dielectric layer and the second semiconductor layer.

8. The SOI substrate of claim 7, wherein the infrared barrier layer is infrared reflective and has substantially zero infrared transmittance.

9. The SOI substrate of claim 8, wherein the infrared barrier layer is composed of a metal-containing material having a thickness from 20 nm to 5 μm.

10. The SOI substrate of claim 9, wherein the metal-containing material that provides the infrared barrier layer comprises titanium, titanium nitride, copper, tantalum, tantalum nitride, chromium, ruthenium, cobalt, tungsten, platinum or palladium.

11. The SOI substrate of claim 7, further comprising an antireflection layer positioned on a second surface of the first semiconductor layer, wherein the second surface is opposite the first surface.

12. The SOI substrate of claim 1, further comprising a first antireflection layer positioned between the first semiconductor layer and the release layer, wherein the first antireflection layer contacts the first surface of the first semiconductor layer.

13. The SOI substrate of claim 12, further comprising a second antireflection layer contacting a second surface of the first semiconductor layer, wherein the second surface of the first semiconductor layer is opposite the first surface of the first semiconductor layer.

14. The SOI substrate of claim 12, further comprising an infrared barrier layer located on the first dielectric layer, and a second dielectric layer located on the infrared barrier layer, wherein the infrared barrier layer and the second dielectric layer are sandwiched between the first dielectric layer and the second semiconductor layer.

15. The SOI substrate of claim 14, wherein the infrared barrier layer is composed of a metal-containing material having a thickness from 100 nm to 500 nm.

16. The SOI substrate of claim 15, wherein the metal-containing material that provides the infrared barrier layer comprises Ti, TiN, Cu, Ta, TaN, Cr, Ru, Co, W, Pt or Pd.

17. The SOI substrate of claim 14, further comprising a second antireflection layer contacting a second surface of the first semiconductor layer, wherein the second surface of the first semiconductor layer is opposite the first surface of the first semiconductor layer.

18. The SOI substrate of claim 1, wherein the second semiconductor layer is a semiconductor device layer containing one or more semiconductor devices located thereon.

19. The SOI substrate of claim 1, wherein the first semiconductor layer comprises a first semiconductor material and the semiconductor layer comprises a second semiconductor material, wherein the first semiconductor is compositionally the same as the second semiconductor material.

20. The SOI substrate of claim 1, wherein the first semiconductor layer comprises a first semiconductor material and the semiconductor layer comprises a second semiconductor material, wherein the first semiconductor is compositionally different from the second semiconductor material.
